(19) United States
(12) Patent Application Publication
(10) Pub. No.: US 2025/0282980 A1
(43) Pub. Date: Sep. 11, 2025

(54) SHEET PROVIDED WITH HEAT INSULATING LAYER AND ADHESIVE LAYER

(71) Applicant: Resonac Corporation, Tokyo (JP)

(72) Inventors: Nozomi MATSUBARA, Tokyo (JP); Tomoko HIGASHIUCHI, Tokyo (JP); Hiroshi YOKOTA, Tokyo (JP); Yoshihiro TSUDA, Tokyo (JP); Naoki FURUKAWA, Tokyo (JP)

(21) Appl. No.: 18/860,583

(22) PCT Filed: Jun. 14, 2023
(86) PCT No.: PCT/JP2023/022124

§ 371 Date: Oct. 25, 2024

(30) Foreign Application Priority Data
Jun. 21, 2022 (JP) 2022-099813

(51) Int. Cl. C09J 7/20; C09J 7/38; F16L 59/02

(52) U.S. Cl. CPC C09J 7/20; C09J 7/38; F16L 59/02

(57) ABSTRACT

A sheet including a thermal insulation layer and an adhesive layer, in which a bulk strength of the thermal insulation layer after being subjected to a thermal history of increasing temperature from 25 to 200° C. at a temperature increase rate of 47° C./min and then increasing temperature from 200 to 260° C. at a temperature increase rate of 38° C./min, is greater than a 90° peel strength of the adhesive layer after being subjected to the above-described thermal history.

### TECHNICAL FIELD

The present invention relates to a sheet including a thermal insulation layer and an adhesive layer.

### BACKGROUND ART

Non-volatile memories, which are characterized by low power consumption and high-speed reading and writing, are attracting attention as next-generation memories. For example, phase change memory (PCM), magnetoresistive memory (MRAM), and resistance change memory (ReRAM) are known. Non-volatile memories are susceptible to heat, and maintaining the quality when the non-volatile memories are exposed to a high-temperature environment in a reflow step during mounting has been an issue.

With regard to this issue, for example, Patent Literature 1 discloses a method for manufacturing a magnetic recording device, the method including a reflow step having: a first step of providing a thermal insulation material on a surface of a magnetic recording device, the surface being exposed in a reflow furnace; a second step of passing the magnetic recording device provided with the thermal insulation material through a reflow furnace and heating the magnetic recording device; and a third step of removing the thermal insulation material from the magnetic recording device heated in the second step.

### CITATION LIST

### Patent Literature

Patent Literature 1: Japanese Unexamined Patent Publication No. 2017-224663

### SUMMARY OF INVENTION

### Technical Problem

The inventors of the present invention have investigated the use of a sheet including a thermal insulation layer and an adhesive layer as a thermal insulation material described above. When such a thermal insulation material is used, the thermal insulation material is provided on an adherend (magnetic recording device) by adhering the adhesive layer to the adherend; however, when the thermal insulation material is peeled from the adherend after a reflow step, there is a risk that the adhesive layer may remain on the adherend side without being peeled together with the thermal insulation layer (for example, peeling may occur between the layers constituting the thermal insulation material). For that reason, it is preferable to use a thermal insulation material having such excellent peelability that the adhesive layer does not remain on the adherend side when peeled after the reflow step.

Thus, it is an object of one aspect of the present invention to provide a sheet appropriate for a thermal insulation material having excellent peelability after a reflow step.

### Solution to Problem

As a result of the investigation of the present inventors, it has been revealed that depending on the combination of the thermal insulation layer and the adhesive layer, when it is attempted to peel the sheet from the adherend after a reflow step, the adhesive layer may not be peeled together with the thermal insulation layer and may remain on the adherend side. The present inventors further conducted intensive research, and as a result, they found that in a sheet including a thermal insulation layer and an adhesive layer, peelability after a reflow step can be improved by making the bulk strength of the thermal insulation layer after the reflow step greater than the 90° peel strength of the adhesive layer after the reflow step. According to some aspects, the present invention provides the following [1] to [3].

[1] A sheet including:
a thermal insulation layer; and
an adhesive layer,
wherein a bulk strength of the thermal insulation layer after being subjected to a thermal history of increasing temperature from 25 to 200° C. at a temperature increase rate of 47° C./min and then increasing temperature from 200 to 260° C. at a temperature increase rate of 38° C./min, is greater than a 90° peel strength of the adhesive layer after being subjected to the thermal history.

[2] The sheet according to [1], wherein the sheet is used as a thermal insulation material in a reflow step in a manufacture of a semiconductor device.

[3] A method for manufacturing a semiconductor device, the method including:
a step of disposing the sheet according to [1] or [2] on a semiconductor device;
a step of subjecting the semiconductor device on which the sheet is disposed, to reflow; and
a step of peeling the sheet from the semiconductor device.

### Advantageous Effects of Invention

According to the present invention, a sheet appropriate for a thermal insulation material having excellent peelability after a reflow step can be provided.

### BRIEF DESCRIPTION OF DRAWINGS

FIG. 1 is a schematic cross-sectional view illustrating an embodiment of a sheet.

FIG. 2 is a schematic cross-sectional view illustrating an embodiment of a disposition step.

FIG. 3 is a schematic cross-sectional view illustrating another embodiment of the disposition step.

FIG. 4 is a schematic cross-sectional view illustrating another embodiment of the disposition step.

FIG. 5 is a schematic cross-sectional view illustrating another embodiment of the disposition step.

### DESCRIPTION OF EMBODIMENTS

Embodiments of the present invention will be described in detail below. Incidentally, the present invention is not intended to be limited to the following embodiments.

The term “(meth)acryloyl” in the present specification means “acryloyl” and “methacryloyl” corresponding thereto, and the same also applies to similar expressions such as “(meth)acrylate” and “(meth)acryl”.

The weight average molecular weight (Mw) according to the present specification means a value measured by using gel permeation chromatography (GPC) under the following conditions and determined by using polystyrene as a standard substance.
Measuring instrument: HLC-8320GPC (product name, manufactured by Tosoh Corporation)
Analytical column: TSKgel SuperMultipore HZ-H (three pieces connected together) (product name, manufactured by Tosoh Corporation)
Guard column: TSKguardcolumn SuperMP (HZ)-H (product name, manufactured by Tosoh Corporation)
Eluent: THF
Measurement temperature: 25° C.

### <Sheet>

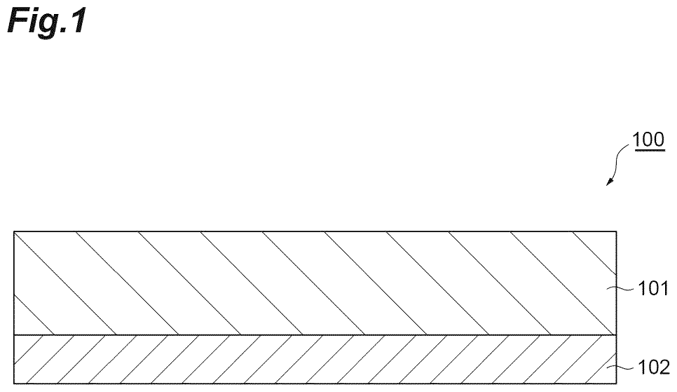

FIG. 1 is a schematic cross-sectional view illustrating an embodiment of a sheet. The sheet 100 shown in FIG. 1 includes a thermal insulation layer 101 and an adhesive layer 102. The thermal insulation layer 101 and the adhesive layer 102 may be laminated so as to be in contact with each other. In this sheet 100, the bulk strength of the thermal insulation layer 101 and the 90° peel strength of the adhesive layer 102 after being subjected to a predetermined thermal history satisfy a specific relationship.

Specifically, the bulk strength of the thermal insulation layer 101 after being subjected to a thermal history of increasing the temperature from 25° C. to 200° C. at a temperature increase rate of 47° C./min and then increasing the temperature from 200° C. to 260° C. at a temperature increase rate of 38° C./min (hereinafter, this thermal history is also referred to as “specific thermal history”), is greater than the 90° peel strength of the adhesive layer 102 after being subjected to the specific thermal history. Generally, in a reflow step, the inside of the reflow furnace is heated stepwise up to about 260° C. When the sheet 100 is provided with the thermal insulation layer 101 and the adhesive layer 102 such that the bulk strength of the thermal insulation layer 101 and the 90° peel strength of the adhesive layer 102 in the sheet 100 satisfy the above-described magnitude relationship, the peelability after a reflow step of the sheet 100 is improved.

In the present specification, the bulk strength of the thermal insulation layer 101 means the magnitude of force required when a cut is provided in a direction perpendicular to the thickness direction of the thermal insulation layer 101, and the thermal insulation layer 101 is broken at the cut as a starting point at 25° C. The bulk strength of the thermal insulation layer 101 is measured, for example, according to the method described in the Examples using a tensile tester.

In the present specification, the 90° peel strength of the adhesive layer 102 means the magnitude of force required when the adhesive layer 102 is stuck to a Si wafer, and the adhesive layer 102 is peeled off in a 90° direction at 25° C. The peel strength of the adhesive layer 102 is measured, for example, according to the method described in the Examples using a tensile tester.

Incidentally, the bulk strength of the thermal insulation layer 101 and the 90° peel strength of the adhesive layer 102 are measured after subjecting the thermal insulation layer 101 and the adhesive layer 102 to the specific thermal history and then leaving the thermal insulation layer 101 and the adhesive layer 102 to cool to reach 25° C. The temperature of the environment in which the layers are left to cool is any temperature; and, in one embodiment, the thermal insulation layer 101 and the adhesive layer 102 may be left to cool to 60° C. in an environment at 60° C. and then left to cool to reach 25° C. in an environment at 25° C.

The difference between the bulk strength of the thermal insulation layer 101 and the 90° peel strength of the adhesive layer 102 ((bulk strength of thermal insulation layer 101)-(90° peel strength of adhesive layer 102)) after being subjected to the specific thermal history may be, for example, 10 N/m or more or 20 N/m or more, and may be 400 N/m or less or 300 N/m or less.

The bulk strength of the thermal insulation layer 101 after being subjected to the specific thermal history may be, for example, 30 N/m or more or 50 N/m or more, and may be 500 N/m or less.

The 90° peel strength of the adhesive layer 102 after being subjected to the specific thermal history may be, for example, 5 N/m or more, and may be 300 N/m or less or 200 N/m or less.

The thermal insulation layer 101 may be any layer having thermal insulation properties and having a bulk strength that satisfies the above-described conditions. The thermal conductivity at 25° C. of the thermal insulation layer 101 is preferably 100 mW/(m·K) or less, 90 mW/(m·K) or less, or 80 mW/(m·K) or less.

The material of the thermal insulation layer 101 is not particularly limited. The thermal insulation layer 101 may be a layer composed of a porous material. The porous material may be an organic porous material, or may be an inorganic porous material. Examples of the organic porous material include a porous material made of a resin. Examples of the porous material made of a resin include a porous material made of a melamine resin (melamine sponge), a porous material made of a polyimide resin (polyimide foam), and a porous material made of an aramid resin (aramid felt). Examples of the inorganic porous material include a porous material made of carbon, and a porous material made of glass. Examples of the porous material made of carbon include carbon felt. Examples of the porous material made of glass include glass fiber paper and glass felt.

The thermal insulation layer 101 may be a layer containing hollow particles. A hollow particle is a particle having an outer shell and a hollow portion. The hollow particles may be organic hollow particles in which the outer shell thereof is composed of an organic material, or may be inorganic hollow particles in which the outer shell thereof is composed of an inorganic material. The hollow particles may contain either organic hollow particles or inorganic hollow particles, or may contain both.

Regarding the organic hollow particles, first hollow particles being thermally expandable organic hollow particles, and second hollow particles being organic hollow particles other than the first hollow particles, may be mentioned. The organic hollow particles may contain either or both of the first hollow particles and the second hollow particles, and preferably, the organic hollow particles contain both the first hollow particles and the second hollow particles.

The first hollow particles are organic hollow particles that expand due to heat (thermally expandable). The thermally expandable organic hollow particles according to the present specification are organic hollow particles whose maximum volumetric expansion ratio with respect to the volume at 25° C. is 10 times or more. When the thermal insulation layer 101 contains the first hollow particles, even in a case where a phenomenon that acts in the direction of deteriorating the thermal insulation properties of the thermal insulation layer 101 has occurred (for example, even in a case where the second hollow particles that will be described below have shrunken, and the volume of the hollow portion has been decreased) in the reflow process, the first hollow particles expand due to heat, and the volume of the hollow portion that contributes to the thermal insulation properties of the thermal insulation layer 101 increases. For that reason, deterioration of the thermal insulation properties of the thermal insulation layer 101 (sheet 100) can be suppressed.

The maximum volumetric expansion ratio of the first hollow particles is measured as the ratio between the maximum volume of the first hollow particles and the volume at 25° C. (maximum volume/volume at 25° C.) when the temperature is increased at a temperature increase rate of 10° C./min in thermomechanical analysis (TMA). The maximum volumetric expansion ratio of the first hollow particles may be, for example, 20 times or more, 30 times or more, or 40 times or more, and may be 120 times or less.

The outer shell of the first hollow particles is preferably composed of a polymer, and is more preferably composed of a thermoplastic polymer. In this case, since the outer shell is softened by heating, even when the liquid enclosed in the hollow portion vaporizes, and the internal pressure increases, the hollow particles are less likely to crack, and the hollow particles expand easily. The thermoplastic polymer may be, for example, a polymer containing acrylonitrile, vinylidene chloride, or the like as a monomer unit. The thickness of the outer shell may be 2 μm or more and may be 15 μm or less.

In the hollow portion of the first hollow particles, for example, a liquid is enclosed. The first hollow particles enclose, for example, a liquid at normal temperature and normal pressure (for example, at least at atmospheric pressure and 30° C.). This liquid is appropriately selected, for example, according to the heating temperature in the reflow step and the shrink initiation temperature of the second hollow particles that will be described below. The liquid is, for example, a liquid that vaporizes at a temperature equal to or lower than the highest heating temperature in the reflow step. The liquid may be a liquid that vaporizes at a temperature equal to or lower than the shrink initiation temperature of the second hollow particles. The liquid may be, for example, a hydrocarbon having a boiling point (at atmospheric pressure) of 50° C. or higher, 100° C. or higher, 150° C. or higher, or 200° C. or higher. In the hollow portion of the first hollow particles, a gas may be further enclosed in addition to the above-described liquid.

Examples of the component enclosed in the hollow portion of the first hollow particles include hydrocarbons such as propane, propylene, butene, normal butane, isobutane, normal pentane, isopentane, neopentane, normal hexane, isohexane, heptane, isooctane, normal octane, isoalkane (number of carbon atoms: 10 to 13), and petroleum ether; low-boiling point compounds such as methane halides and tetraalkylsilanes; and compounds that are gasified by thermal decomposition, such as azodicarbonamide.

The average particle size of the first hollow particles may be 5 μm or more, or 10 μm or more, and may be 50 μm or less, 40 μm or less, or 30 μm or less. The average particle size of the first hollow particles is measured by a laser diffraction and scattering method (for example, using “SALD-7500nano” manufactured by SHIMADZU CORPORATION).

From the viewpoint that the sheet 100 is more suitably used as a thermal insulation material in the reflow step (generally heated up to 260° C.), the expansion initiation temperature of the first hollow particles is preferably equal to or lower than the shrink initiation temperature of the second hollow particles that will be described below. The expansion initiation temperature of the first hollow particles is preferably 150° C. or higher or 180° C. or higher, and is preferably 260° C. or lower, 240° C. or lower, 220° C. or lower, or 200° C. or lower. The expansion initiation temperature of the first hollow particles means, in a temperature (axis of abscissa)-volume change (axis of ordinate) profile obtained when temperature is increased at a temperature increase rate of 10° C./min in thermomechanical analysis (TMA), the temperature at an intersection point between the tangent line at a point where a volumetric change of 3 times or more/5° C. occurs and a straight line (axis of abscissa) where the volumetric change is zero (initial volume).

From the viewpoint that the sheet 100 is more suitably used as a thermal insulation material in the reflow step, the maximum expansion temperature of the first hollow particles is preferably 100° C. or higher, 150° C. or higher, 200° C. or higher, or 210° C. or higher, and is preferably 290° C. or lower, 280° C. or lower, or 270° C. or lower. The maximum expansion temperature of the first hollow particles means the temperature at which the first hollow particles exhibit the above-mentioned maximum volumetric expansion ratio.

From the viewpoint of preventing deterioration of the thermal insulation properties of the sheet 100, the content (content at atmospheric pressure and 30° C.; hereinafter, the same) of the first hollow particles is preferably 1% by mass or more, more preferably 2% by mass or more, even more preferably 4% by mass or more, and particularly preferably 5% by mass or more, and is 20% by mass or less or 15% by mass or less, based on the total mass of the thermal insulation layer 101.

From the viewpoint of preventing deterioration of the thermal insulation properties of the sheet 100, the content of the first hollow particles is preferably 0.5% by volume or more, more preferably 1.0% by volume or more, and even more preferably 1.5% by volume or more, based on the total volume of the thermal insulation layer 101. From the viewpoint of suppressing excessive expansion of the volume of the sheet 100, the content of the first hollow particles may be 10% by volume or less, 7% by volume or less, 5% by volume or less, or 4% by volume or less, based on the total volume of the thermal insulation layer 101.

The second hollow particles are organic hollow particles other than the first hollow particles. That is, the second hollow particles are organic hollow particles whose maximum volumetric expansion ratio with respect to the volume at 25° C. is less than 10 times. By using the second hollow particles, the thermal insulation properties of the thermal insulation layer 101 are improved, and the sheet 100 can be more suitably utilized as a thermal insulation material. The maximum volumetric expansion ratio of the second hollow particles is measured by the same method as that for the maximum volumetric expansion ratio of the first hollow particles.

The outer shell of the second hollow particles is composed of an organic material. The outer shell of the second hollow particles is preferably composed of a polymer, and is more preferably composed of a thermoplastic polymer. In this case, the hollow particles are less likely to crack even when pressure is applied, and can retain a hollow structure, and therefore, the thermal insulation properties of the sheet 100 are easily maintained. The thermoplastic polymer may be, for example, a polymer containing acrylonitrile, vinylidene chloride, or the like as a monomer unit. The thickness of the outer shell may be 0.005 μm or more and may be 15 μm or less.

In the hollow portion of the second hollow particles, for example, a gas is enclosed. The second hollow particles enclose, for example, a gas at normal temperature and normal pressure (for example, at least at atmospheric pressure and 30° C.). In the hollow portion of the second hollow particles, a liquid may be further enclosed in addition to the gas.

Examples of the component enclosed in the hollow portion of the second hollow particles include hydrocarbons such as propane, propylene, butene, normal butane, isobutane, normal pentane, isopentane, neopentane, normal hexane, isohexane, heptane, isooctane, normal octane, isoalkanes (number of carbon atoms: 10 to 13), and petroleum ether; low-boiling point compounds such as methane halides and tetraalkylsilanes; and decomposition products of compounds that are gasified by thermal decomposition, such as azodicarbonamide. Furthermore, the component enclosed in the hollow portion of the second hollow particles may be air.

From the viewpoint of enhancing the thermal insulation properties, the average particle size of the second hollow particles is preferably 150 μm or less, more preferably 120 μm or less, and even more preferably 100 μm or less, and the average particle size may be, for example, 5 μm or more, 10 μm or more, 20 μm or more, or 30 μm or more. The average particle size of the second hollow particles is measured by a laser diffraction and scattering method (for example, using “SALD-7500nano” manufactured by SHIMADZU CORPORATION).

The density of the second hollow particles may be 500 kg/m³ or less, 300 kg/m³ or less, 100 kg/m³ or less, 50 kg/m³ or less, or 40 kg/m³ or less, and may be 10 kg/m³ or more or 20 kg/m³ or more. The density of the second hollow particles according to the present specification means a density measured by a tapped density method. That is, the density is a density determined by introducing the second hollow particles (about 5 g) into a 10-mL graduated cylinder, tapping the graduated cylinder fifty times, and using the volume when the topmost surface is stabilized as the stable volume and using the following formula:

Density=Initial input amount (kg)/stable volume (m³)

From the viewpoint that the sheet 100 is more suitably used as a thermal insulation material in the reflow step (generally heated up to 260° C.), the shrink initiation temperature of the second hollow particles is preferably 150° C. or higher, 170° C. or higher, or 180° C. or higher, and may be 260° C. or lower, 240° C. or lower, 220° C. or lower, or 200° C. or lower. The shrink initiation temperature of the second hollow particles means, in a temperature (axis of abscissa)-volume change (axis of ordinate) profile obtained when temperature is increased at a temperature increase rate of 10° C./min in thermomechanical analysis (TMA), the temperature at which the volume change reaches the maximum value.

From the viewpoint of enhancing the thermal insulation properties of the sheet 100, the content (content at atmospheric pressure and 30° C.; hereinafter, the same) of the second hollow particles is preferably 1% by mass or more, more preferably 3% by mass or more, and even more preferably 5% by mass or more, and may be, for example, 20% by mass or less, based on the total mass of the thermal insulation layer 101.

From the viewpoint of enhancing the thermal insulation properties of the sheet 100, the content of the second hollow particles is preferably 50% by volume or more, and more preferably 60% by volume or more, and may be, for example, 95% by volume or less, based on the total volume of the thermal insulation layer 101.

The mass ratio of the content of the second hollow particles to the content of the first hollow particles (content (mass) of the second hollow particles/content (mass) of the first hollow particles) is preferably ⅕ or more, and more preferably ⅓ or more. The mass ratio of the content of the second hollow particles to the content of the first hollow particles is preferably 3 or less, more preferably 2 or less, and even more preferably 1 or less.

The volume ratio of the content of the second hollow particles to the content of the first hollow particles (content (volume) of the second hollow particles/content (volume) of the first hollow particles) is preferably 10 or more, and more preferably 15 or more. The volume ratio of the content of the second hollow particles to the content of the first hollow particles is preferably 80 or less, more preferably 60 or less, and even more preferably 45 or less.

The inorganic material composing the outer shell of the inorganic hollow particles may be, for example, inorganic glass such as borosilicate glass (sodium borosilicate glass or the like), aluminosilicate glass, or glass obtained by compositizing those. In the hollow portion of the inorganic hollow particles, for example, a gas is enclosed. The inorganic hollow particles enclose, for example, a gas at normal temperature and normal pressure (for example, at least at atmospheric pressure and 30° C.).

The content (content at atmospheric pressure and 30° C.; hereinafter, the same) of the inorganic hollow particles is preferably 20% by mass or more, more preferably 22% by mass or more, and even more preferably 25% by mass or more, and may be 40% by mass or less or 30% by mass or less, based on the total mass of the thermal insulation layer 101.

The content of the inorganic hollow particles is preferably 55% by volume or more, more preferably 60% by volume or more, and even more preferably 63% by volume or more, and may be 80% by volume or less or 75% by volume or less, based on the total volume of the thermal insulation layer 101.

The total content of the hollow particles (total content of the first hollow particles, the second hollow particles, and the inorganic hollow particles at atmospheric pressure and 30° C.; hereinafter, the same) may be, for example, 4% by mass or more, 8% by mass or more, or 10% by mass or more, and may be 40% by mass or less, 35% by mass or less, or 30% by mass or less, based on the total mass of the sheet 100.

The total content of the hollow particles may be, for example, 50% by volume or more, 60% by volume or more, or 70% by volume or more, and may be 95% by volume or less, based on the total volume of the sheet 100.

When the thermal insulation layer 101 contains hollow particles, it is preferable that the thermal insulation layer 101 further contains a matrix polymer. The matrix polymer is a polymer (binder polymer) that serves as a matrix (forming a continuous phase) for holding other materials such as hollow particles that are contained in the thermal insulation layer 101. The hollow particles may be held in the matrix polymer and may be dispersed in the matrix polymer.

The matrix polymer may contain a compound represented by the following Formula (1) as a monomer unit. In other words, the matrix polymer may be a polymer of polymerizable compounds containing a compound represented by the following Formula (1).

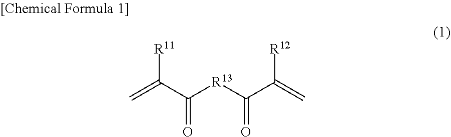

In the Formula (1), R¹¹ and R¹² each independently represent a hydrogen atom or a methyl group; and R¹³ represents a divalent group having a polyoxyalkylene chain.

When the matrix polymer contains a compound represented by the above-described Formula (1) as a monomer unit, the thermal insulation layer 101 has low elasticity and excellent elongation, and therefore, the conformability of the sheet 100 to an adherend can be enhanced.

According to an embodiment, one of R¹¹ and R¹² may be a hydrogen atom, and the other one may be a methyl group. According to another embodiment, both R¹¹ and R¹² may be hydrogen atoms. According to another embodiment, both R¹¹ and R¹² may be methyl groups.

According to an embodiment, the polyoxyalkylene chain contains a structural unit represented by the following Formula (2). As a result, the strength of the thermal insulation layer 101 can be increased.

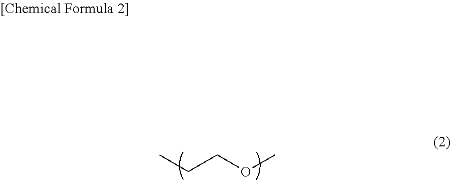

In this case, R¹³ may be a divalent group having a polyoxyethylene chain, and the compound represented by the Formula (1) is preferably a compound represented by the following Formula (1-2) (polyethylene glycol di(meth)acrylate).

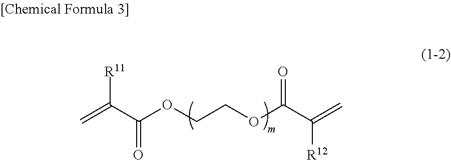

In the Formula (1-2), R¹¹ and R¹² have the same meanings as R¹¹ and R¹² in the Formula (1), respectively, and m is an integer of 2 or greater.

According to another embodiment, the polyoxyalkylene chain contains a structural unit represented by the following Formula (3).

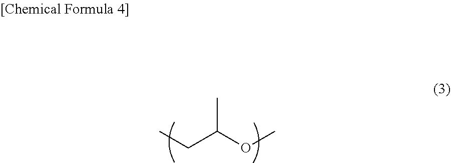

In this case, R¹³ may be a divalent group having a polyoxypropylene chain, and the compound represented by the Formula (1) is preferably a compound represented by the following Formula (1-3) (polypropylene glycol di(meth)acrylate).

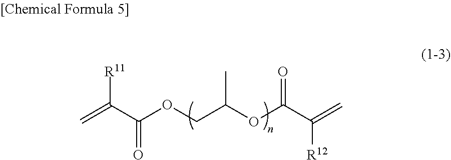

In the Formula (1-3), R¹¹ and R¹² have the same meanings as R¹¹ and R¹² in the Formula (1), respectively, and n is an integer of 2 or greater.

According to another embodiment, the polyoxyalkylene chain is preferably a copolymer chain containing the above-mentioned structural unit represented by the Formula (2) and the above-mentioned structural unit represented by the Formula (3). The copolymer chain may be any of an alternating copolymer chain, a block copolymer chain, or a random copolymer chain. The copolymer chain is preferably a random copolymer chain.

In each of the above-mentioned embodiments, the polyoxyalkylene chain may have an oxyalkylene group having 4 or 5 carbon atoms, such as an oxytetramethylene group, an oxybutylene group, or an oxypentylene group, as a structural unit in addition to the structural unit represented by the Formula (2) and the structural unit represented by the Formula (3).

R¹³ may also be a divalent group further having an additional organic group in addition to the above-mentioned polyoxyalkylene chain. The additional organic group may be a chain-shaped group other than a polyoxyalkylene chain, and examples include a methylene chain (a chain having —CH₂— as a structural unit), a polyester chain (a chain containing —COO— in a structural unit), and a polyurethane chain (a chain containing —OCON— in a structural unit).

For example, the compound represented by the Formula (1) may be a compound represented by the following Formula (1-4).

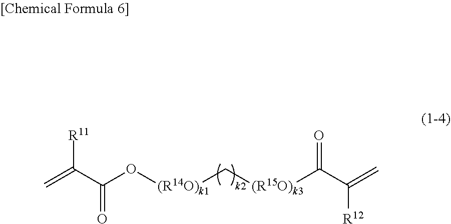

In the Formula (1-4), R¹¹ and R¹² have the same meanings as R¹¹ and R¹² in the Formula (1), respectively; R¹⁴ and R¹⁵ each independently represent an alkylene group having 2 to 5 carbon atoms; and k1, k2, and k3 each independently represent an integer of 2 or greater. k2 may be, for example, an integer of 16 or less.

A plurality of R¹⁴ and a plurality of R¹⁵ present therein may be respectively identical to each other or may be different from each other. A plurality of R¹⁴ and a plurality of R¹⁵ present therein each preferably contain an ethylene group and a propylene group. That is, each of the polyoxyalkylene chain represented by (R¹⁴O)ₖ₁ and the polyoxyalkylene chain represented by (R¹⁵O)ₖ₃ is preferably a copolymer chain containing an oxyethylene group (the above-described structural unit represented by the Formula (2)) and an oxypropylene group (the above-described structural unit represented by the Formula (3)).

In each of the above-mentioned embodiments, the number of oxyalkylene groups in the polyoxyalkylene chain is preferably 100 or greater. When the number of oxyalkylene groups in the polyoxyalkylene chain is 100 or greater, as the main chain of the compound represented by the Formula (1) is lengthened, the elongation of the thermal insulation layer 101 is more excellent, and the strength of the thermal insulation layer 101 can also be increased. The number of oxyalkylene groups corresponds to each of m in the Formula (1-2), n in the Formula (1-3), and k1 and k3 in the Formula (1-4).

The number of oxyalkylene groups in the polyoxyalkylene chain is more preferably 130 or greater, 180 or greater, 200 or greater, 220 or greater, 250 or greater, 270 or greater, 300 or greater, or 320 or greater. The number of oxyalkylene groups in the polyoxyalkylene chain may be 600 or less, 570 or less, or 530 or less.

From the viewpoint that the thermal insulation layer 101 has low elasticity and excellent elongation, the weight average molecular weight of the compound represented by the Formula (1) is preferably 5000 or more, 6000 or more, 7000 or more, 8000 or more, 9000 or more, 10000 or more, 11000 or more, 12000 or more, 13000 or more, 14000 or more, or 15000 or more. The weight average molecular weight of the compound represented by the Formula (1) is preferably 100000 or less, 80000 or less, 60000 or less, 34000 or less, 31000 or less, or 28000 or less.

The matrix polymer may contain only the compound represented by the Formula (1) as the monomer unit. The matrix polymer may further contain an additional polymerizable compound (the details will be described below) other than the compound represented by the Formula (1), as a monomer unit. In this case, from the viewpoint that the thermal insulation layer 101 has lower elasticity and more excellent elongation, the content of the compound represented by the Formula (1) is preferably 20 parts by mass or more, 30 parts by mass or more, or 40 parts by mass or more, with respect to 100 parts by mass of the sum of the compound represented by the Formula (1) and the other polymerizable compound (hereinafter, referred to as “total content of the monomer units”). The content of the compound represented by the Formula (1) may be 80 parts by mass or less, 70 parts by mass or less, or 60 parts by mass or less, with respect to 100 parts by mass of the total content of the monomer units.

The additional polymerizable compound (monomer unit) in the matrix polymer may be, for example, a compound having one (meth)acryloyl group. An example of this compound may be a compound having a (meth)acryloyl group, which can be contained as a monomer unit in an acrylic copolymer that will be described below. The additional polymerizable compound in the matrix polymer may also be a compound having, in addition to the one (meth)acryloyl group, an aromatic hydrocarbon group, a group containing a polyoxyalkylene chain, an alkoxy group, a phenoxy group, a group containing a silane group, a group containing a siloxane bond, a halogen atom, an amino group, or an epoxy group. Particularly, when the matrix polymer contains a compound having a hydroxyl group, a carboxyl group, an amino group, or an epoxy group in addition to a (meth)acryloyl group, the adhesiveness of the thermal insulation layer 101 to other members can be further improved.

Examples of a compound having a (meth)acryloyl group and an aromatic hydrocarbon group include benzyl (meth)acrylate.

Examples of a compound having a (meth)acryloyl group and a group containing a polyoxyalkylene chain include polyethylene glycol (meth)acrylate, methoxy polyethylene glycol (meth)acrylate, polypropylene glycol (meth)acrylate, methoxy polypropylene glycol (meth)acrylate, polybutylene glycol (meth)acrylate, and methoxy polybutylene glycol (meth)acrylate.

Examples of a compound having a (meth)acryloyl group and an alkoxy group include 2-methoxyethyl acrylate.

Examples of a compound having a (meth)acryloyl group and a phenoxy group include phenoxyethyl (meth)acrylate.

Examples of a compound having a (meth)acryloyl group and a group containing a silane group include 3-acryloxypropyltriethoxysilane, 10-methacryloyloxydecyltrimethoxysilane, 10-acryloyloxydecyltrimethoxysilane, 10-methacryloyloxydecyltriethoxysilane, and 10-acryloyloxydecyltriethoxysilane.

Examples of a compound having a (meth)acryloyl group and a group containing a siloxane bond include silicone (meth)acrylate.

Examples of a compound having a (meth)acryloyl group and a halogen atom include (meth)acrylates having fluorine atoms, such as trifluoromethyl (meth)acrylate, 2,2,2-trifluoroethyl (meth)acrylate, 1,1,1,3,3,3-hexafluoro-2-propyl (meth)acrylate, perfluoroethylmethyl (meth)acrylate, perfluoropropylmethyl (meth)acrylate, perfluorobutylmethyl (meth)acrylate, perfluoropentylmethyl (meth)acrylate, perfluorohexylmethyl (meth)acrylate, perfluoroheptylmethyl (meth)acrylate, perfluorooctylmethyl (meth)acrylate, perfluorononylmethyl (meth)acrylate, perfluorodecylmethyl (meth)acrylate, perfluoroundecylmethyl perfluorododecylmethyl (meth)acrylate, (meth)acrylate, perfluorotridecylmethyl (meth)acrylate, perfluorotetradecylmethyl (meth)acrylate, 2-(trifluoromethyl) ethyl (meth)acrylate, (meth)acrylate, 2-(perfluoropropyl) ethyl 2-(perfluoroethyl) ethyl (meth)acrylate, 2-(perfluorobutyl) ethyl (meth)acrylate, 2-(perfluoropentyl) ethyl (meth)acrylate, 2-(perfluorohexyl) ethyl (meth)acrylate, 2-(perfluoroheptyl) ethyl (meth)acrylate, 2-(perfluorooctyl) ethyl (meth)acrylate, 2-(perfluorononyl) ethyl (meth)acrylate, 2-(perfluorotridecyl) ethyl (meth)acrylate, and 2-(perfluorotetradecyl) ethyl (meth)acrylate.

Examples of a compound having a (meth)acryloyl group and an amino group include N,N-dimethylaminoethyl (meth)acrylate, N,N-diethylaminoethyl (meth)acrylate, N,N-dimethylaminopropyl (meth)acrylate, and N,N-diethylaminopropyl (meth)acrylate.

Examples of a compound having a (meth)acryloyl group and an epoxy group include glycidyl (meth)acrylate, glycidyl «-ethyl (meth)acrylate, glycidyl α-n-propyl (meth)acrylate, glycidyl «-n-butyl (meth)acrylate, 3,4-epoxybutyl (meth)acrylate, 4,5-epoxypentyl (meth)acrylate, 6,7-epoxyheptyl (meth)acrylate, 6,7-epoxyheptyl α-ethyl (meth)acrylate, 3-methyl-3,4-epoxybutyl (meth)acrylate, 4-methyl-4,5-epoxypentyl (meth)acrylate, 5-methyl-5,6-epoxyhexyl (meth)acrylate, β-methylglycidyl (meth)acrylate, and β-methylglycidyl α-ethyl (meth)acrylate.

The matrix polymer may contain one kind of the above-described additional polymerizable compounds, or may contain two or more kinds thereof, as a monomer unit. Furthermore, the matrix polymer may or may not further contain the compound represented by the Formula (1).

The content of the matrix polymer may be, for example, 40% by mass or more, 50% by mass or more, 60% by mass or more, or 70% by mass or more, and may be 95% by mass or less, or 90% by mass or less, based on the total mass of the thermal insulation layer 101.

The thermal insulation layer 101 may further contain additional additives as necessary. Examples of the additional additives include a plasticizer, an antioxidant (for example, a phenol-based antioxidant), a surface conditioning agent (for example, a silane coupling agent), a dispersant, a curing accelerator, a colorant, a crystal nucleating agent, a thermal stabilizer, a foaming agent, a flame retardant, a damping agent, a dehydrating agent, and a flame retardant aid (for example, a metal oxide). The content of the additional additives may be 0.1% by mass or more and may be 30% by mass or less, based on the total mass of the thermal insulation layer 101.

The thickness of the thermal insulation layer 101 may be, for example, 100 μm or more, 200 μm or more, or 500 μm or more, and may be 10 mm or less, 5 mm or less, or 2 mm or less.

The adhesive layer 102 may contain a known adhesive. The adhesive layer 102 may contain, for example, an acrylic adhesive or an epoxy-based adhesive. The acrylic adhesive may contain, for example, an acrylic copolymer and a crosslinking agent.

The acrylic copolymer is a copolymer of two or more kinds of polymerizable compounds. The two or more kinds of polymerizable compounds contain one or more kinds of a compound having a (meth)acryloyl group. The acrylic copolymer contains one or more kinds of a compound having a (meth)acryloyl group as a monomer unit; and the acrylic copolymer may contain two or more kinds, three or more kinds, or four or more kinds of the compound having a (meth)acryloyl group as a monomer unit.

The compound having a (meth)acryloyl group may be, for example, an alkyl (meth)acrylate. The alkyl group (alkyl group moiety other than the (meth)acryloyl group) in the alkyl (meth)acrylate may be linear, branched, or cyclic. The number of carbon atoms of the alkyl group may be, for example, 1 to 30. The number of carbon atoms of the alkyl group may be 2 or more, or 3 or more, and may be 25 or less, 20 or less, 15 or less, 10 or less, 7 or less, or 5 or less.

Examples of the compound having a (meth)acryloyl group include an alkyl (meth)acrylate having a linear alkyl group having 1 to 11 carbon atoms, an alkyl (meth)acrylate having a branched alkyl group having 1 to 11 carbon atoms, a compound having a (meth)acryloyl group and a group containing a heterocyclic ring, a compound having a (meth)acryloyl group and a hydroxyl group, and a compound having a (meth)acryloyl group and a carboxyl group.

Examples of the alkyl (meth)acrylate having a linear alkyl group having 1 to 11 carbon atoms include methyl (meth)acrylate and butyl (meth)acrylate. Examples of the alkyl (meth)acrylate having a branched alkyl group having 1 to 11 carbon atoms include 2-ethylhexyl (meth)acrylate. Examples of the compound having a (meth)acryloyl group and a group containing a heterocyclic ring include N-acryloylmorpholine (ACMO). Examples of the compound having a (meth)acryloyl group and a hydroxyl group include 2-hydroxyethyl (meth)acrylate. Examples of the compound having a (meth)acryloyl group and a carboxyl group include (meth)acrylic acid.

The acrylic copolymer may contain an additional polymerizable compound other than the compound having a (meth)acryloyl group, as a monomer unit. Examples of the additional polymerizable compound (monomer unit) in the acrylic copolymer include acrylonitrile.

The weight average molecular weight (Mw) of the acrylic copolymer may be 50000 or more, 100000 or more, or 200000 or more, and may be 1200000 or less, 1100000 or less, or 1000000 or less.

The content of the acrylic copolymer may be 70% by mass or more, and may be 98% by mass or less or 95% by mass or less, based on the total mass of the adhesive layer 102.

The crosslinking agent may be, for example, a crosslinking agent having an epoxy group, or a crosslinking agent having an isocyanate group. The crosslinking agent having an epoxy group may have two or more, three or more, or four or more epoxy groups. Examples of a crosslinking agent having four epoxy groups include N,N,N′,N′-tetraglycidyl-1,3-bis(aminomethyl) cyclohexane, and N,N,N′,N′-tetraglycidyl-m-xylenediamine.

The crosslinking agent having an isocyanate group may have two or more isocyanate groups or three or more isocyanate groups. Examples of the crosslinking agent having three isocyanate groups include “CORONATE L” (manufactured by Tosoh Corporation).

The thickness of the adhesive layer 102 may be, for example, 5 μm or more or 10 μm or more, and may be 200 μm or less, 100 μm or less, or 50 μm or less.

The sheet 100 may consist of the thermal insulation layer 101 and the adhesive layer 102, as in the embodiment shown in FIG. 1. According to another embodiment, the sheet may further include a layer other than the thermal insulation layer and the adhesive layer. In this case, in the sheet, the thermal insulation layer and the adhesive layer may be in contact with each other (may be laminated without any other layer interposed therebetween), or the thermal insulation layer and the adhesive layer may be laminated with an additional layer interposed therebetween. Examples of the additional layer include a surface protective layer, a bonding adhesive layer, and a support layer.

According to one embodiment, a sheet including another layer may be a sheet including a surface protective layer (first surface protective layer), a thermal insulation layer, a bonding adhesive layer (first bonding adhesive layer), a support layer (first support layer), a bonding adhesive layer (second bonding adhesive layer), a support layer (second support layer), an adhesive layer, and a surface protective layer (second surface protective layer). The surface protective layer may be composed of, for example, a resin film (PET film or the like) whose surface that comes into contact with the thermal insulation layer or the adhesive layer has been easy-release treated. The bonding adhesive layer may contain, for example, an acrylic bonding adhesive or an epoxy-based bonding adhesive. The support layer may be composed of, for example, a resin film (polyimide film or the like).

The thickness of the sheet 100 may be, for example, 100 μm or more, 200 μm or more, or 500 μm or more, and may be 11 mm or less, 5 mm or less, 3 mm or less, or 2 mm or less.

The sheet 100 can be produced by, for example, producing each of the thermal insulation layer 101 and the adhesive layer 102, and sticking the thermal insulation layer 101 and the adhesive layer 102 together. For example, a method for manufacturing the above-described sheet including an additional layer may include: a step of preparing each of a laminated body A of a surface protective layer (first surface protective layer) and a thermal insulation layer, a laminated body B of a bonding adhesive layer (first bonding adhesive layer), a support layer (first support layer), and a bonding adhesive layer (second bonding adhesive layer), and a laminated body C of a support layer (second support layer), an adhesive layer, and a surface protective layer (second surface protective layer); and a step of sticking the thermal insulation layer of the laminated body A and the bonding adhesive layer (first bonding adhesive layer) of the laminated body B together and sticking the bonding adhesive layer (second bonding adhesive layer) of the laminated body B and the support layer (second support layer) of the laminated body C.

The laminated body A is obtained by, for example, preparing a mixture containing the above-mentioned first hollow particles, the second hollow particles, and the polymerizable compound, and then polymerizing the polymerizable compound in the mixture on a surface protective layer (first surface protective layer) to form a matrix polymer. As the laminated body B, for example, a double-sided bonding adhesive tape including: a support layer (first support layer); and a bonding adhesive layer (first bonding adhesive layer) and a bonding adhesive layer (second bonding adhesive layer) respectively provided on the two surfaces of the support layer, can be used. The laminated body C is obtained by, for example, applying an adhesive composition obtained by mixing materials such as an acrylic adhesive, on a surface protective layer (second surface protective layer), proceeding drying of the adhesive composition and/or curing of curable components in the adhesive composition to form an adhesive layer, and then providing a support layer (second support layer) on a surface of the adhesive layer on the opposite side from the surface protective layer (second surface protective layer). In the step of sticking the laminated body A, the laminated body B, and the laminated body C together, for example, a roll laminator can be used.

Since the sheet 100 described above has excellent peelability after a reflow step, the sheet 100 is suitably used as a thermal insulation material in a reflow step. The sheet 100 may also be a sheet used as a thermal insulation material in a reflow step in the manufacture of a semiconductor device.

### <Method for Manufacturing Semiconductor Device>

Another embodiment of the present invention is a method for manufacturing a semiconductor device, the method including: a step of disposing a sheet on a semiconductor device; a step of subjecting the semiconductor device on which the sheet is disposed, to reflow; and a step of peeling the sheet from the semiconductor device.

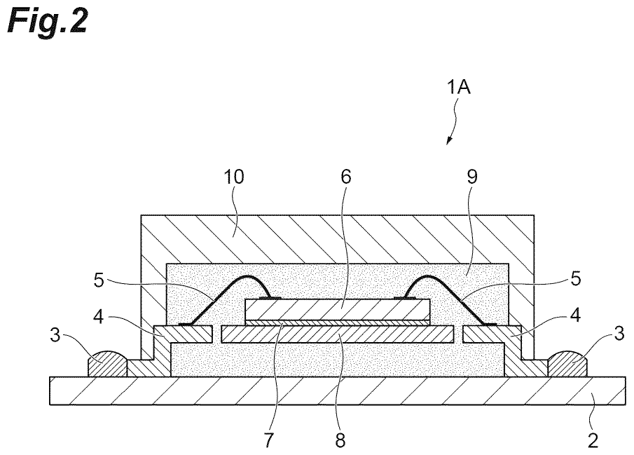

FIG. 2 is a schematic cross-sectional view illustrating an embodiment of a disposition step. As shown in FIG. 2, a semiconductor device (also called semiconductor package) 1A used in the disposition step includes, for example, a substrate 2, leads 4 connected to the substrate 2 with solder (solder paste) 3, and a semiconductor chip 6 connected to the leads 4 through wires 5. The semiconductor chip 6 is mounted on a die pad 8, with a die attach material 7 interposed therebetween, and is also covered with a encapsulant material 9.

The sheet is disposed on at least a portion of the surface of such a semiconductor device 1A. In one embodiment, the sheet 10 is disposed on the semiconductor device 1A so as to cover the entire surface of the encapsulant material 9. In another embodiment, the sheet 10 may be disposed so as to cover a portion (for example, only the top face) of the surface of the encapsulant material 9.

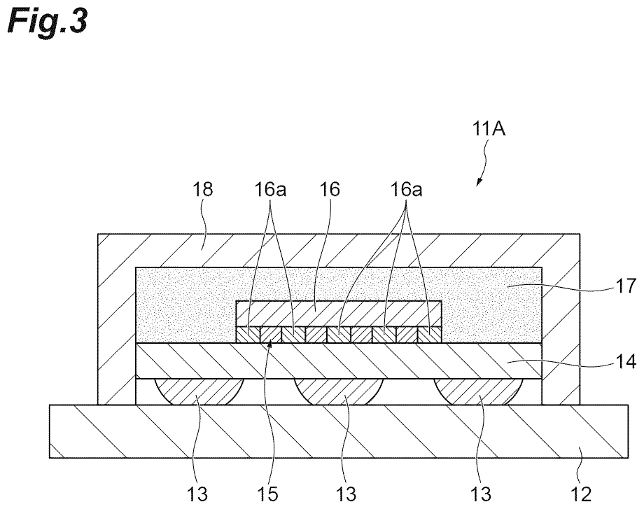

FIG. 3 is a schematic cross-sectional view illustrating another embodiment of the disposition step. As shown in FIG. 3, in another embodiment, a semiconductor device 11A used in the disposition step includes, for example, a substrate 12, an interposer 14 connected to the substrate 12 with solder (solder balls) 13, and a semiconductor chip 16 connected to the interposer 14 with a bonding adhesive 15 interposed therebetween. The semiconductor chip 16 is connected to the interposer 14 by a plurality of protruding electrodes (bumps) 16a. The semiconductor chip 16 is covered with a encapsulant material 17 disposed on the interposer 14.

The sheet is disposed on at least a portion of the surface of such a semiconductor device 11A. In one embodiment, the sheet 18 is disposed on the semiconductor device 11A so as to cover the entire surface of the encapsulant material 17 and all of the side faces of the place where the solder (solder balls) 13 and the interposer 14 are disposed.

As another embodiment of the disposition step shown in FIG. 3, the sheet 18 may be disposed so as to cover the entire surface of the encapsulant material 17 and only the side faces of the place where the interposer 14 is disposed (the sheet 18 does not have to be disposed on the side faces of the place where the solder (solder balls) 13 is disposed). In another embodiment, the sheet 18 may be disposed so as to cover only the entire surface of the encapsulant material 17, or may be disposed so as to cover only a portion of the surface (for example, top face) of the encapsulant material 17. Even in these cases, the semiconductor device can be suitably protected from heat in the reflow step. However, for example, in a case where low-temperature solder is used as the solder (solder balls) 13, from the viewpoint that the solder (solder balls) 13 is protected from excess heat in the reflow step, and damage to the solder junctions can be suppressed, the sheet 18 is preferably disposed so as to cover the entire surface of the encapsulant material 17 and all of the side faces of the place where the solder (solder balls) 13 and the interposer 14 are disposed, as shown in FIG. 3.

In another embodiment, a plurality of semiconductor devices (semiconductor packages) may be mounted on a single substrate 2 or 12, and some or all of the plurality of semiconductor devices may be the above-mentioned semiconductor devices 1A or 11A. When some of the plurality of semiconductor devices are the above-mentioned semiconductor devices 1A or 11A, the remaining semiconductor devices may be semiconductor devices that are more heat-resistant (having higher heat resistance) than the above-mentioned semiconductor devices 1A or 11A, and the solder in the remaining semiconductor devices may be solder that is joined at a higher temperature compared to solder 3 or 13 in the above-mentioned semiconductor devices 1A or 11A. In this way, even when a plurality of semiconductor devices (semiconductor packages) having different heat resistances are mounted on a single substrate 2 or 12, by disposing the sheet 10 or 18 on the semiconductor devices 1A or 11A that are weaker to heat (having lower heat resistance), a plurality of semiconductor devices (semiconductor packages) having different heat resistances can be subjected to the reflow step all at once.

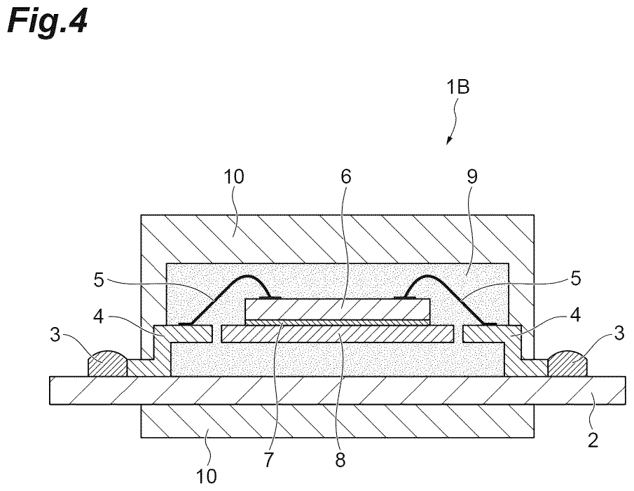

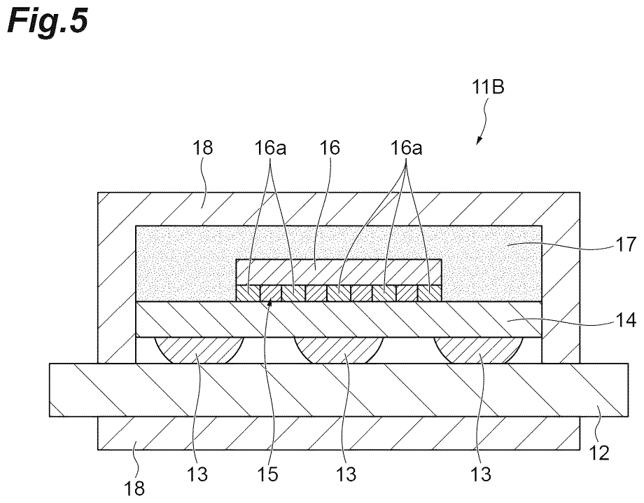

In another embodiment, the sheet may be disposed on a surface of the substrate on the opposite side of the surface on which the semiconductor chip is mounted. FIG. 4 is a schematic cross-sectional view illustrating another embodiment of the disposition step shown in FIG. 2. As shown in FIG. 4, the sheet 10 is also disposed on a surface of the substrate 2 on the opposite side of the surface on which the semiconductor chip 6 is mounted. Furthermore, FIG. 5 is a schematic cross-sectional view illustrating another embodiment of the disposition step shown in FIG. 3. As shown in FIG. 5, the sheet 18 is also disposed on a surface of the substrate 12 on the opposite side of the surface on which the semiconductor chip 16 is mounted. In these embodiments, for example, when a plurality of semiconductor devices (semiconductor packages) having different heat resistances are mounted on a single substrate 2 or 12, or the like, by disposing more sheets 10 or 18 on semiconductor devices 1B or 11B that are weaker to heat (having lower heat resistance), a plurality of semiconductor devices (semiconductor packages) having different heat resistances can be subjected to the reflow step all at once.

In the disposition step, it is preferable that the sheet is disposed such that the semiconductor device (semiconductor package) surface and the adhesive layer of the sheet are disposed to be in contact with each other. In the disposition step, the method of disposing the sheet may include a pressure-bonding step of pressure-bonding the sheet onto the semiconductor device (semiconductor package) in a vacuum or at atmospheric pressure.

In the pressure-bonding step, specifically, for example, first, a cushioning material (for example, a rubber sheet), a release film, a semiconductor device (semiconductor package), the sheet, and a release film are stacked in this order in a chamber of a vacuum laminator (for example, “V-130” manufactured by Nikko-Materials Co., Ltd.). Subsequently, a vacuum is drawn inside the chamber, and then by applying pressure so that the sheet closely adheres to the semiconductor device (semiconductor package), the sheet can be pressure-bonded to the semiconductor device (semiconductor package). As another specific example, first, a semiconductor device (semiconductor package), a sheet, and a release film are stacked in this order on a support (for example, a stainless steel plate). Subsequently, the assembly is inserted into a roll laminator (for example, “VA-770H Special Type Laminator” manufactured by TAISEI LAMINATOR CO., LTD.), and by applying pressure so that the sheet closely adheres to the semiconductor device (semiconductor package), the sheet can be pressure-bonded to the semiconductor device (semiconductor package).

In the reflow step following the disposition step, the semiconductor device is subjected to reflow by a known method. Specifically, for example, the semiconductor device is put inside a reflow furnace, the temperature inside the furnace is gradually increased to reach a maximum temperature of 240 to 260° C., and then the temperature is gradually decreased. As a result, the solder paste is sintered, and the wiring board is electrically connected to the substrate.

In the peeling step following the reflow step, the sheet is peeled from the semiconductor device. The method of peeling is not particularly limited, and for example, a method of attaching an adhesive film to the sheet, and pulling the adhesive film to peel the sheet may be adopted. Furthermore, the method of peeling may also be, for example, a method of peeling the sheet by pressing a roller against the sheet, with a support film interposed therebetween, and winding the sheet together with the support film. As the support film, for example, a double-sided tape can be used. In order to peel, an apparatus such as a tape remover (for example, “OTR-600SA” manufactured by OHMIYA IND. CO., LTD.) may be used.

### EXAMPLES

Hereinafter, the present invention will be described more specifically based on Examples; however, the present invention is not intended to be limited to these Examples.

### Example 1

### [Synthesis of Compound Represented by the Formula (1-5)]

A 500-mL flask equipped with a stirrer, a thermometer, a nitrogen gas inlet tube, a discharge tube, and a heating jacket was used as a reactor, 225 g of a glycol having a polyoxyalkylene chain (“NEWPOL 75H-90000” manufactured by Sanyo Chemical Industries, Ltd.) and 300 g of toluene were introduced into the reactor, the mixture was stirred at 45° C. and a speed of stirring rotation of 250 times/min, nitrogen was allowed to flow at a rate of 100 mL/min, and the mixture was stirred for 30 minutes. Subsequently, the temperature was lowered to 25° C., and after completion of the temperature lowering, 2.9 g of acryloyl chloride was added dropwise into the reactor, followed by stirring for 30 minutes. Subsequently, 3.8 g of triethylamine was added dropwise, and the mixture was stirred for 2 hours. Subsequently, the temperature was raised to 45° C., and the mixture was allowed to react for 2 hours. The reaction liquid was filtered, the filtrate was desolvated, and a compound represented by the Formula (1-5) (weight average molecular weight: 15000, a mixture in which m1+m2 in the Formula (1-5) represents an integer of approximately 252±5, n1+n2 represents an integer of approximately 63±5 (provided that m1, m2, n1, and n2 are each an integer of 2 or greater, m1+n1≥100, and m2+n2≥100), viscosity at 25° C.: 50 Pa·s) was obtained.

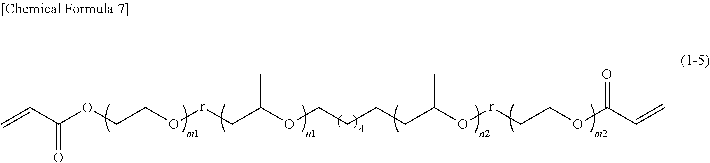

[in the Formula (1-5), -r- is a symbol representing random copolymerization.]

### [Production of Thermal Insulation Layer]

39.2% by mass of the compound represented by the Formula (1-5), 23.5% by mass of dicyclopentanyl acrylate (“FANCRYL (registered trademark) FA-513A” manufactured by Showa Denko Materials Co., Ltd.), 15.7% by mass of 4-hydroxybutyl acrylate (manufactured by OSAKA ORGANIC CHEMICAL INDUSTRY LTD.), 11.0% by mass of first hollow particles (“MATSUMOTO MICROSPHERE (registered trademark) FN-190SSD” manufactured by Matsumoto Yushi-Seiyaku Co., Ltd., average particle size: 10 to 15 μm, maximum volumetric expansion ratio: 50 times or more, expansion initiation temperature: 190° C., maximum expansion temperature: 210 to 220° C.), 5.8% by mass of second hollow particles (“Expancel (registered trademark) 920DE80d30” manufactured by Japan Fillite Co., Ltd., average particle size 60 to 90 μm, density 30±3 kg/m³, maximum volumetric expansion ratio: less than 5 times, shrink initiation temperature: 200° C.), 0.9% by mass of a polymerization initiator (“PERBUTYL (registered trademark) O” manufactured by NOF CORPORATION), 3.1% by mass of a phenol-based antioxidant (“Irganox 1010” manufactured by BASF Japan Ltd.), and 0.8% by mass of a surface conditioning agent (“BYK (registered trademark) 350” manufactured by BYK) were mixed, and a composition for producing a thermal insulation layer was obtained. Incidentally, based on the total amount of the composition for producing a thermal insulation layer, the blending amount of the first hollow particles was 3.8% by volume, and the blending amount of the second hollow particles was 67.3% by volume.

Two sets of molding plates were prepared by placing a mold release-treated polyester sheet (“A31” manufactured by TOYOBO CO., LTD.) that measured 200 mm in length×200 mm in width×0.1 mm in thickness on a glass plate that measured 200 mm in length×200 mm in width×5 mm in thickness, with the mold release-treated surface facing upward. A formwork (200 mm×200 mm) made of silicone rubber, in which a hole having a size of 120 mm×120 mm×2.0 mm was formed, was installed on the mold release-treated surface of one of the molding plates, and the inside of the formwork was filled with the composition for producing a thermal insulation layer. The other molding plate was placed, with the mold release-treated surface facing the composition side, to serve as a top lid, and then the composition was heated for 40 minutes under the conditions of 135° C. Thereafter, one of the molding plates, the formwork made of silicone rubber, and the glass plate on the other molding plate were removed, and a laminated body (laminated body A) of a surface protective layer (polyester sheet) and a thermal insulation layer (thickness 2.0 mm) was produced. Furthermore, the thermal insulation layer was obtained by peeling the surface protective layer of the laminated body A. Regarding this thermal insulation layer, the initial thermal conductivity measured by a method that will be described below was 63 mW/(m·K), and the thermal conductivity after heating was 67 mW/(m·K).

### [Production of Adhesive Layer]

An acrylic copolymer resin (weight average molecular weight: 200000) containing methyl acrylate (MA), 2-ethylhexyl acrylate (EHA), acrylic acid (AA), and 2-hydroxyethyl acrylate (HEA) as monomer units at a ratio of MA:EHA:AA:HEA=50:40:0.5:9.5 on a mass basis, was used. 100 parts by mass of an ethyl acetate solution (solid content 35% by mass) of this acrylic copolymer resin, 5 parts by mass of an isocyanate (trade name: CORONATE L, manufactured by Tosoh Corporation) as a crosslinking agent, 7 parts by mass of a decafunctional urethane acrylate (trade name: U-10PPA, manufactured by SHIN-NAKAMURA CHEMICAL Co., Ltd.) as a photocurable resin, and 0.21 parts by mass of a photopolymerization initiator (trade name: Irgcure 819, manufactured by BASF) were dissolved in a mixed solvent of toluene and methyl ethyl ketone such that the solid content was 25% by mass. Next, the mixture was stirred in a rotation-revolution mixer for 5 minutes at a speed of rotation of 1000 rpm, and then was left to stand at normal temperature until all air bubbles disappeared, to obtain an adhesive composition.

The obtained adhesive composition was applied on an easy-release treated surface of a polyester film (trade name: PUREX A31, manufactured by TOYOBO CO., LTD.) having a thickness of 38 μm, whose one surface had been subjected to an easy-release treatment with a silicone-based release agent, and then dried in a drying oven at 100° C. for 2 minutes, and the photocurable resin was cured by irradiating the adhesive composition with ultraviolet radiation having a wavelength of 365 nm at a dose of 300 mJ/cm², to form an adhesive layer having a thickness of 10 μm. Next, by laminating a polyimide film base material (trade name: KAPTON 100H, manufactured by DU PONT-TORAY CO., LTD.) having a thickness of 25 μm on the exposed surface of the formed adhesive layer at room temperature (25° C.), a laminated body (laminated body C) in which a surface protective layer (polyester film), an adhesive layer, and a support layer (polyimide film base material) were laminated in this order was produced. Furthermore, a support layer-attached adhesive layer was obtained by peeling the surface protective layer of the laminated body C. Regarding this adhesive layer, the initial 90° peel strength measured by a method that will be described below was 7 N/m.

### [Production of Sheet]

Using a roll laminator (HOT DOCK LMP-350EX manufactured by Lami Corporation Inc.), a bonding adhesive tape (tape including a support layer and bonding adhesive layers provided on both surfaces of the support layer, manufactured by Showa Denko Materials Co., Ltd., HI-BON 11-652) was laminated on the support layer side of the laminated bodies C. In addition, the laminated body A was laminated on the tape using the above-described roll laminator such that the tape and the thermal insulation layer were in contact with each other, to obtain a sheet of Example 1. The thickness of the sheet of Example 1 was 2135 μm.

### Example 2

A sheet of Example 2 was obtained in the same manner as in Example 1, except that carbon felt (“CARBON FELT F-350” manufactured by ASAHI SANGYO CO., LTD., thickness: 2.8 mm) was used as the thermal insulation layer, and this thermal insulation layer was used instead of the laminated body A. Regarding the thermal insulation layer used in Example 2, the initial thermal conductivity measured by a method that will be described below was 61 mW/(m·K), and the thermal conductivity after heating was 53 mW/(m·K). The thickness of the sheet of Example 2 was 2935 μm.

### Example 3

A sheet of Example 3 was obtained in the same manner as in Example 1, except that in the production of the thermal insulation layer, the composition for producing a thermal insulation layer was changed to a composition for producing a thermal insulation layer produced as described below. 35.19% by mass of a compound represented by the Formula (1-5), 21.12% by mass of dicyclopentanyl acrylate (“FANCRYL (registered trademark) FA-513A” manufactured by Showa Denko Materials Co., Ltd.), 14.08% by mass of 4-hydroxybutyl acrylate (manufactured by OSAKA ORGANIC CHEMICAL INDUSTRY LTD.), 25.21% by mass of inorganic hollow particles (“Q-CEL 5020” manufactured by Potters Ballotini Co., Ltd., average particle size: 60 μm, density 0.20 g/cm³), 0.84% by mass of a polymerization initiator (“PERBUTYL (registered trademark) O” manufactured by NOF CORPORATION), 2.82% by mass of a phenol-based antioxidant (“Irganox 1010” manufactured by BASF Japan Ltd.), and 0.74% by mass of a surface conditioning agent (“BYK (registered trademark) 350” manufactured by BYK) were mixed, and a composition for producing a thermal insulation layer was obtained. Incidentally, the blending amount of the inorganic hollow particles based on the total amount of the composition for producing a thermal insulation layer was 63% by volume. Regarding the thermal insulation layer used in Example 3, the initial thermal conductivity measured by a method that will be described below was 130 mW/(m·K), and the thermal conductivity after heating was 125 mW/(m·K). The thickness of the sheet of Example 3 was 2135 μm.

### Example 4

A sheet of Example 4 was obtained in the same manner as in Example 1, except that a melamine sponge (“BASOTECT G+” manufactured by INOAC CORPORATION, thickness: 2.5 mm) was used as the thermal insulation layer, and this thermal insulation layer was used instead of the laminated body A. Regarding the thermal insulation layer used in Example 4, the initial thermal conductivity measured by a method that will be described below was 35 mW/(m·K), and the thermal conductivity after heating was 38 mW/(m·K). The thickness of the sheet of Example 4 was 2635 μm.

### Example 5

A sheet of Example 5 was obtained in the same manner as in Example 1, except that glass fiber paper (“SB-150TS” manufactured by ORIBEST CO., LTD., thickness: 0.95 mm) was used as the thermal insulation layer, and this thermal insulation layer was used instead of the laminated body A. Regarding the thermal insulation layer used in Example 5, the initial thermal conductivity measured by a method that will be described below was 43 mW/(m·K), and the thermal conductivity after heating was 40 mW/(m·K). The thickness of the sheet of Example 5 was 1085 μm.

### Comparative Example 1

A sheet of Comparative Example 1 was obtained in the same manner as in Example 1, except that glass felt (“Heat-Resistant Glass Felt B” manufactured by A&A Material Corporation, thickness: 5 mm) was used as the thermal insulation layer, and this thermal insulation layer was used instead of the laminated body A. Regarding the thermal insulation layer used in Comparative Example 1, the initial thermal conductivity measured by a method that will be described below was 35 mW/(m·K), and the thermal conductivity after heating was 37 mW/(m·K). The thickness of the sheet of Comparative Example 1 was 5135 μm.

### Example 6

A sheet of Example 6 was obtained in the same manner as in Example 1, except that in the production of the adhesive layer, an acrylic copolymer resin (weight average molecular weight: 200000) containing 2-ethylhexyl acrylate (EHA) and 2-hydroxyethyl acrylate (HEA) as monomer units at a ratio of EHA:HEA=65:35 on a mass basis was used instead of the above-described acrylic copolymer resin. Regarding this adhesive layer, the initial 90° peel strength measured by a method that will be described below was 38 N/m. The thickness of the sheet of Example 6 was 2135 μm.

### Example 7

A sheet of Example 7 was obtained in the same manner as in Example 6, except that the same carbon felt (“CARBON FELT F-350” manufactured by ASAHI SANGYO CO., LTD., thickness: 2.8 mm) used in Example 2 was used as the thermal insulation layer, and this thermal insulation layer was used instead of the laminated body A. The thickness of the sheet of Example 7 was 2935 μm.

### Example 8

A sheet of Example 8 was obtained in the same manner as in Example 6, except that the same thermal insulation layer used in Example 3 was used as the thermal insulation layer. The thickness of the sheet of example 8 was 2135 μm.

### Comparative Example 2

A sheet of Comparative Example 2 was obtained in the same manner as in Example 6, except that the same melamine sponge (“BASOTECT G+” manufactured by INOAC CORPORATION, thickness: 2.5 mm) used in Example 4 was used as the thermal insulation layer, and this thermal insulation layer was used instead of the laminated body A. The thickness of the sheet of Comparative Example 2 was 2635 μm.

### Comparative Example 3

A sheet of Comparative Example 3 was obtained in the same manner as in Example 6, except that the same glass fiber paper (“SB-150TS” manufactured by ORIBEST CO., LTD., thickness: 0.95 mm) used in Example 5 was used as the thermal insulation layer, and this thermal insulation layer was used instead of the laminated body A. The thickness of the sheet of Comparative Example 3 was 1085 μm.

### Comparative Example 4

A sheet of Comparative Example 4 was obtained in the same manner as in Example 6, except that the same glass felt (“Heat-Resistant Glass Felt B” manufactured by A&A Material Corporation, thickness: 5 mm) used in Comparative Example 1 was used as the thermal insulation layer, and this thermal insulation layer was used instead of the laminated body A. The thickness of the sheet of Comparative Example 4 was 5135 μm.

### <Evaluation>

[Bulk Strength after Heating of Thermal Insulation Layer]

The bulk strength after heating of the thermal insulation layer used in each of Examples and Comparative Examples was measured by the following procedure. Each thermal insulation layer was cut into a size of 20 mm×50 mm to produce rectangular parallelepiped-shaped test pieces that measured 20 mm (side x)×50 mm (side y)×2 mm (side z), each of the test pieces was passed through a reflow furnace (TNP25-337 EM series N2 reflow apparatus manufactured by TAMURA CORPORATION) to be subjected to a thermal history, and the test piece was left to cool. Specifically, the thermal history was applied by increasing the temperature from room temperature (25° C.) to 200° C. at a temperature increase rate of 47° C./min and then increasing the temperature from 200 to 260° C. at a temperature increase rate of 38° C./min in the reflow furnace. Furthermore, when left to cool, specifically, the test piece was cooled to 60° C. in the reflow furnace, taken out from the reflow furnace, and cooled to 25° C. Thereafter, the test piece was left to stand at 25° C. for 24 hours, and then the bulk strength in the thickness direction at 25° C. of each thermal insulation layer was measured using a tensile tester (“Autograph EZ-TEST EZ-S” manufactured by SHIMADZU CORPORATION). Specifically, first, a cut having a depth of 15 mm was inserted using a cutter in a direction perpendicular to the side z from the plane including the side x and the side z of each sample, and thereby one end of the test piece was bifurcated to form two ends. The two ends were each clamped by the chucks of a tensile tester and were pulled under the conditions of a distance between chucks of 20 mm and a tensile speed of 5 mm/min, and the magnitude of force at which the test piece broke was measured as the bulk strength. The results are shown in Table 1 and Table 2.

### [Measurement of Thermal Conductivity of Thermal Insulation Layer]

The thermal conductivity of the thermal insulation layer used in each of Examples and Comparative Examples was measured by the following procedure. The thermal insulation layer was cut into a size of 8 cm×13 cm×2.0 mm and was sandwiched between a reference plate and a measurement probe, and the thermal conductivity (initial thermal conductivity) was measured with a rapid thermal conductivity meter (“QTM-710” manufactured by Kyoto Electronics Manufacturing Co., Ltd., measurement probe PD-11N, thin film measurement mode) under the conditions of 25° C. Furthermore, the thermal insulation layer was subjected to a thermal history in the same manner as in the above-described section [Bulk strength after heating of thermal insulation layer] and was left to cool, and then the thermal conductivity (thermal conductivity after heating) was measured in the same manner. The reference was measured by stacking two sheets of a mold release-treated polyester sheet (“A31” manufactured by TOYOBO CO., LTD.) and sandwiching the sheets between a reference plate and a measurement probe.

### [90° Peel Strength of Adhesive Layer]

The 90° peel strength of the adhesive layer used in each of Examples and Comparative Examples was measured by the following procedure. A Si wafer that measured 25 mm in length×70 mm in width and a support layer-attached adhesive layer cut into a size of 20 mm in length×60 mm in width were prepared. The support layer-attached adhesive layer was installed on the Si wafer such that the adhesive layer and the Si wafer were in contact with each other, and no air bubbles were trapped between the two. The Si wafer on which the support layer-attached adhesive layer was installed was placed on a stainless steel plate that measured 380 mm in length×500 mm in width×0.5 mm in thickness, and the adhesive layer and the Si wafer were stuck using a roll laminator (“VA-770H Special Type Laminator” manufactured by TAISEI LAMINATOR CO., LTD.) under the conditions of a pressure of 6 kgf/cm², a speed of rotation of 0.2 rpm, and a temperature of 40° C., to produce a sample. The support layer-attached adhesive layer of the obtained sample was cut to a width of 5 mm, a portion of 10 mm on one side in the length direction was peeled from the Si wafer, and the 90° peel strength (initial 90° peel strength) was measured using a tensile tester (“Autograph EZ-TEST EZ-S” manufactured by SHIMADZU CORPORATION). Furthermore, the sample was subjected to a thermal history in the same manner as in the above-described section [Bulk strength after heating of thermal insulation layer] and was left to cool, and then the peel strength (90° peel strength after heating) was measured in the same manner. The results are shown in Table 1 and Table 2.

### [Peelability of Sheet]

The surface protective layer of the sheet of each of Examples and Comparative Examples was completely peeled off, and the sheet was stuck to a Si wafer using a roll laminator (“VA-770H Special Type Laminator” manufactured by TAISEI LAMINATOR CO., LTD.) under the conditions of a pressure of 6 kgf/cm², a speed of rotation of 0.2 rpm, and a temperature of 40° C. such that the adhesive layer was in contact with the Si wafer, to produce a sample. The sample was subjected to a thermal history in the same manner as in the above-described section [Bulk strength after heating of thermal insulation layer] and was left to cool. Thereafter, one surface (surface where a bonding adhesive layer was exposed) of a double-sided tape (tape including a support layer and bonding adhesive layers provided on both surfaces of the support layer. Has a release film on one of the bonding adhesive layers. “HI-BON 11-652” manufactured by Showa Denko Materials Co., Ltd.) was stuck onto the thermal insulation layer of the sheet. The release film on the other surface of the double-sided tape was peeled, and the sheet was peeled by pressing a roller against the surface of the double-sided tape, to which the release film had been attached, and winding the sheet together with the double-sided tape. At this time, a case in which peeling occurred at the interface between the adhesive layer and the Si wafer, and the adhesive layer was peeled together with the thermal insulation layer and the like, was evaluated to be “OK”, and a case in which peeling occurred at the interface between the layers constituting the sheet, and a portion of the sheet including the adhesive layer remained on the Si wafer, was evaluated to be “NG”. The results are shown in Table 1 and Table 2.

TABLE 1

| | | | | | | | Comparative |
|---|---|---|---|---|---|---|---|
| | | Example 1 | Example 2 | Example 3 | Example 4 | Example 5 | Example 1 |
| Thermal | Bulk | 176 | 411 | 229 | 65 | 55 | 9.5 |
| insulation | strength | | | | | | |
| layer | after heating | | | | | | |
| | (N/m) | | | | | | |
| Adhesive | 90° Peel | 28 | 28 | 28 | 28 | 28 | 28 |
| layer | strength | | | | | | |
| | after heating | | | | | | |
| | (N/m) | | | | | | |
| Sheet | Peelability | OK | OK | OK | OK | OK | NG |

TABLE 2

| | | | | | Comparative | Comparative | Comparative |
|---|---|---|---|---|---|---|---|
| | | Example 6 | Example 7 | Example 8 | Example 2 | Example 3 | Example 4 |
| Thermal | Bulk strength | 176 | 411 | 229 | 65 | 55 | 9.5 |
| insulation | after heating | | | | | | |
| layer | (N/m) | | | | | | |
| Adhesive | 90° Peel | 155 | 155 | 155 | 155 | 155 | 155 |
| layer | strength after | | | | | | |
| | heating | | | | | | |
| | (N/m) | | | | | | |
| Sheet | Peelability | OK | OK | OK | NG | NG | NG |

### REFERENCE SIGNS LIST

1A, 1B, 11A, 11B: semiconductor device, 2, 12: substrate, 3: solder (solder paste), 4: lead, 5: wire, 6, 16: semiconductor chip, 7: die attach material, 8: die pad, 9, 17: encapsulant material, 10, 18, 100: sheet, 13: solder (solder ball), 14: interposer, 15: bonding adhesive, 16a: protruding electrode, 101: thermal insulation layer, 102: adhesive layer.

1. A sheet comprising:
a thermal insulation layer; and
an adhesive layer,
wherein a bulk strength of the thermal insulation layer after being subjected to a thermal history of increasing temperature from 25 to 200° C. at a temperature increase rate of 47° C./min and then increasing temperature from 200 to 260° C. at a temperature increase rate of 38° C./min, is greater than a 90° peel strength of the adhesive layer after being subjected to the thermal history.

2. The sheet according to claim 1, wherein the sheet is used as a thermal insulation material in a reflow step in a manufacture of a semiconductor device.

3. A method for manufacturing a semiconductor device, the method comprising:
a step of disposing the sheet according to claim 1 on a semiconductor device;
a step of subjecting the semiconductor device on which the sheet is disposed, to reflow; and
a step of peeling the sheet from the semiconductor device.
